(19) United States
(12) Patent Application Publication
(10) Pub. No.: US 2020/0241423 A1
(43) Pub. Date: Jul. 30, 2020

(54) APPARATUS FOR REMOVING PHOTORESISTS AND METHOD OF MANUFACTURING SEMICONDUCTOR DEVICE USING THE SAME

(71) Applicant: Samsung Electronics Co., Ltd., Suwon-si (KR)

(72) Inventors: Hyun Jung LEE, Suwon-si (KR); Ji Hun CHEON, Suwon-si (KR); Won Jun LEE, Seoul (KR)

(73) Assignee: Samsung Electronics Co., Ltd., Suwon-si (KR)

(21) Appl. No.: 16/577,372

(22) Filed: Sep. 20, 2019

(30) Foreign Application Priority Data
Jan. 24, 2019 (KR) 10-2019-0009408

(51) Int. Cl. G03F 7/42; H01L 21/67

(52) U.S. Cl. CPC G03F 7/423; H01L 21/67051

(57) ABSTRACT

An apparatus for removing photoresists includes a chamber including a substrate support, configured to support a substrate, and a nozzle unit disposed toward the substrate support, an ozone solution generator configured to generate an ozone solution, an acid solution reservoir configured to store an acid solution, first and second supply lines connected to the ozone solution generator and the acid solution reservoir respectively, and an in-line mixer configured to prepare a photoresist removing solution by mixing the ozone solution supplied from the first supply line, and the acid solution supplied from the second supply line, and supply the photoresist removing solution to the nozzle unit.

### CROSS-REFERENCE TO RELATED APPLICATION(S)

This application claims benefit of priority to Korean Patent Application No. 10-2019-0009408 filed on Jan. 24, 2019 in the Korean Intellectual Property Office, the disclosure of which is incorporated herein by reference in its entirety.

### BACKGROUND

### 1. Field

The disclosure relates to an apparatus for removing photoresists, and more particularly, to a method of manufacturing a semiconductor device using the same.

### 2. Description of Related Art

In a method of manufacturing a semiconductor device, a lithography process is used to form patterns on a wafer. In the lithography process, a photoresist is used to transfer a desired pattern to the wafer. After the lithography process, the photoresist may be removed using a photoresist cleaning solution.

In such a stripping process, photoresist residues may be produced when removability of organic matter is not sufficient. Particularly, a harmful photoresist cleaning solution (for example, H₂SO₄) may be used.

### SUMMARY

Example embodiments provide an apparatus for removing photoresist which has improved removability of an organic matter and performs an eco-friendly process.

Example embodiments also provide a method of manufacturing a semiconductor device using an apparatus for removing photoresist which has improved removability of an organic matter and performs an eco-friendly process.

According to some example embodiments, an apparatus for removing photoresists includes a chamber including a substrate support, configured to support a substrate, and a nozzle unit disposed toward the substrate support, an ozone solution generator configured to generate an ozone solution, an acid solution reservoir configured to store an acid solution, first and second supply lines connected to the ozone solution generator and the acid solution reservoir respectively, and an in-line mixer configured to prepare a photoresist removing solution by mixing the ozone solution, supplied from the first supply line, and the acid solution, supplied from the second supply line, and supply the photoresist removing solution to the injection nozzle unit.

According to some example embodiments, an apparatus for removing photoresists includes a chamber having an internal space, an ozone solution generator configured to generate an ozone solution, an acid solution reservoir configured to store an acid solution, first and second supply lines, connected to the ozone solution generator and the acid solution reservoir respectively, including first and second valves configured to control flow rates of the ozone solution and the acid solution, respectively, a transfer line having a first end connected to the first and second supply lines, and a second end connected to the internal space of the chamber, an in-line mixer configured to prepare a photoresist removing solution by mixing the ozone solution, supplied from the first supply line, and the acid solution, supplied from the second supply line, and supply the photoresist removing solution to the internal space of the chamber through the transfer line, and a flow rate controller configured to control the first and second valves.

According to some example embodiments, an apparatus for removing photoresists includes a chamber having an internal space, an ozone solution generator configured to generate an ozone solution, an acid solution reservoir configured to store an acid solution, an in-line mixer configured to prepare a photoresist removing solution by mixing the ozone solution and the acid solution and supply the photoresist removing solution to the internal space of the chamber, and a flow rate controller configured to control flow rates of the ozone solution and the acid solution.

According to some example embodiments, a method of manufacturing a semiconductor device includes forming a photoresist pattern on a semiconductor substrate, processing the semiconductor substrate using the photoresist pattern, removing the photoresist pattern, photoresist residues being produced after removing the photoresist pattern, preparing a photoresist removing solution by mixing an ozone solution and an acid solution using an in-line mixer, and removing the photoresist residues using the photoresist removing solution.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic diagram illustrating a configuration of an apparatus for removing photoresists according to some example embodiments;

FIGS. 2A and 2B are a side cross-sectional view and an inlet cross-sectional view of an in-line mixer employable in the apparatus for removing photoresists in FIG. 1, respectively;

FIG. 3 is a cross-sectional view illustrating a mixing-in-flow process of the in-line mixer in FIG. 2;

FIG. 4 is a flowchart illustrating a method of manufacturing a semiconductor device according to some example embodiments;

FIG. 5 is a flowchart illustrating a process of removing a photoresist according to some example embodiments;

FIGS. 6 and 7 are graphs illustrating etching rates of a silicon nitride and an oxide depending on a concentration of hydrofluoric acid (HF), respectively;

FIG. 8 is a graph illustrating production rates of photoresist residues according to a comparative example and an example of the inventive concepts; and

FIGS. 9 to 14 are cross-sectional views illustrating a method of manufacturing a semiconductor device according to some example embodiments.

### DETAILED DESCRIPTION

Hereinafter, some example embodiments will be described with reference to the accompanying drawings.

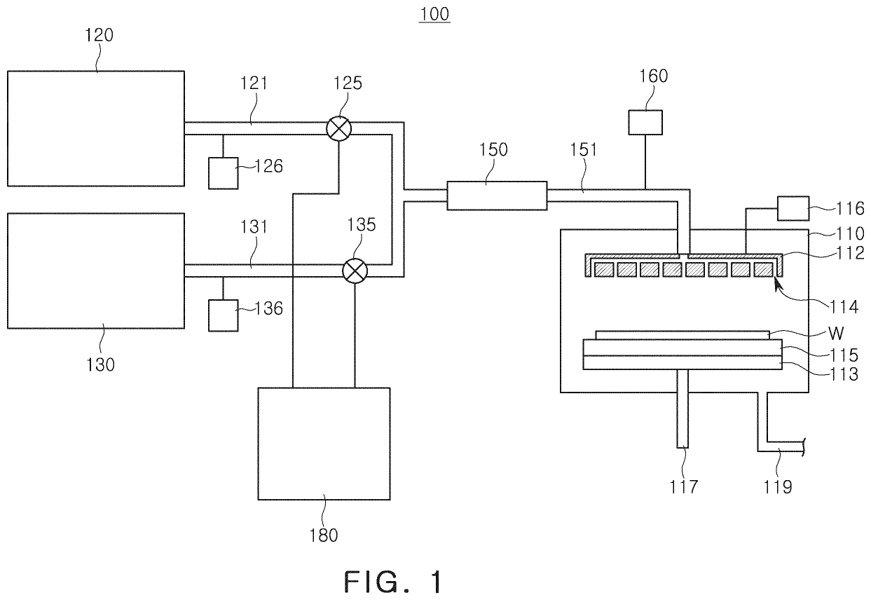

FIG. 1 is a schematic diagram illustrating a configuration of an apparatus for removing photoresists according to some example embodiments.

Referring to FIG. 1, an apparatus 100 for removing photoresists according to some example embodiments includes a chamber 110, in which photoresist removal is performed, an ozone generator 120, an acid solution reservoir 130, and an in-line mixer 150.

The apparatus 100 uses a photoresist removing solution in which an ozone solution, generated in the ozone generator 120, and an acid solution, stored in the acid solution reservoir 130, are mixed. In some example embodiments, the photoresist removing solution may be mixed by the in-line mixer 150, while flowing, on a path through which the photoresist removing solution is supplied to the chamber 110. Thus, the mixed photoresist removing solution may be supplied to a chamber for removal of the photoresist while stably maintaining an activated ozone.

Hereinafter, a process of preparing a photoresist removing solution and a process of removing photoresist according to some example embodiments will be described in detail with reference to main components of the apparatus 100 for removing photoresists.

The ozone generator 120 dissolves ozone (O₃), to act as a main etchant for decomposition of an organic matter, in deionized water (DI water) to prepare an ozone solution. The ozone solution is an oxidizing solution containing ozone (O₃) and DI water and acts as a stronger oxidizer than hydrogen peroxide. An etchant is not reduced by byproducts in oxidation and decomposition of ozone (O₃), unlike in an oxidation reaction of sulfuric acid.

Accordingly, the ozone solution may effectively remove organic matter such as photoresist. Since the ozone solution is decomposed in a solution and does not produce a reaction product harmful to a human body, the amount of wastewater may be reduced to provide eco-friendly and economical advantages.

In some example embodiments, the ozone solution may generate a desired concentration of ozonated water in a manner of injecting ozone into deionized water using a pressure pump. The concentration of ozone in the ozone solution may be slightly higher than a prescribed or required concentration of ozone in a photoresist removing solution. For example, when a final photoresist removing solution prescribes or requires an ozone concentration ranging from 20 to 40 ppm, an ozone solution of about 30 to 100 ppm may be generated.

The acid solution reservoir 130 may store an acid solution in which an acid compound is dissolved in deionized water. In a photoresist removing process, when the above-described ozone generator 120 generates an ozone solution having strong oxidation power and such an oxidation radical disconnects a carbon bond of an organic matter to oxidize the organic matter, an acid component in the photoresist removing solution may etch and remove an oxidized resultant. For example, the acid compound may include at least one of hydrofluoric acid (HF), hydrochloric acid (HCl), phosphoric acid (H₃PO₄), tetramethylammonium hydroxide (TMAT), oxalic acid, and/or acetic acid.

In some example embodiments, a diluted hydrofluoric acid (HF) solution may be used as an acid solution. Similarly to the ozone concentration condition, an acid concentration may be slightly higher than a prescribed or required acid concentration in the photoresist removing solution.

In some example embodiments, the ozone solution and the acid solution may be supplied through first and second supply lines 121 and 131 respectively connected to the ozone solution generator 120 and the acid solution reservoir 130. First and second valves 125 and 135 may be mounted on the first and second supply lines 121 and 131, respectively. The first and second valves 125 and 135 may be controlled to control a flow rate of the ozone solution and a flow rate of the acid solution, respectively. Such control of the flow rates may be used to adjust the ozone concentration and the acid concentration of the photoresist removing solution to a desired range.

A concentration meter 160 may be mounted between the in-line mixer 150 and the chamber 110. In some example embodiments, the concentration meter 160 may be mounted on a portion of a transfer line 151 between the in-line mixer 150 and the chamber 110. The concentration meter 160 may measure the concentration of the photoresist removing solution, supplied from the in-line mixer 150 to the chamber 110, for example, the ozone concentration and the acid concentration. A desired concentration condition may be implemented by manipulating the first and second valves 125 and 135 based on information of the measured concentration.

In some example embodiments, the information of the concentration measured by the concentration meter 160 is transmitted to a flow rate controller 180. The flow rate controller 180 may change each flow rate through automatic manipulation of the first and second valves 125 and 135 to obtain a desired concentration. In some example embodiments, the information of the concentration measured by the concentration meter 160 may be monitored by an operator, and the operator may manipulate the flow rate controller 180 based on judgment of the operator to adjust a flow rate condition to a desired flow rate condition.

First and second flow meters 126 and 136 may be mounted on the first and second supply lines 121 and 131, respectively. Real-time flow rate information may be obtained through the first and second flow meters 126 and 136. In some example embodiments, a real-time flow rate may be fed back to the flow rate controller 180 to be adjusted to a desired flow rate.

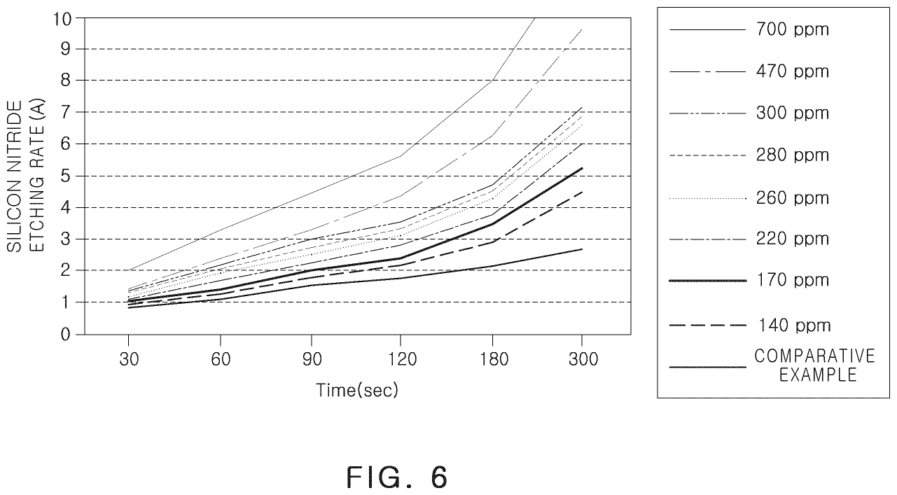

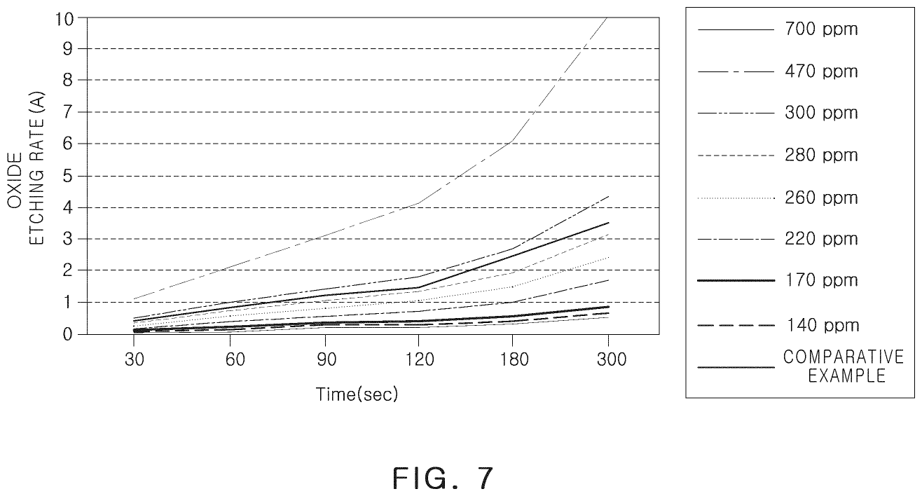

Depending on the use conditions, it is important to appropriately adjust the ozone concentration and the acid concentration of the photoresist removing solution. In general, the higher the concentration of ozone in the photoresist removing solution, the greater the removability of photoresist. However, a mask, used in a pattering process, or a material layer (for example, a silicon nitride), used as a spacer, may be oxidized by an oxidation action of ozone to cause unwanted etching to be performed by an acid solution (for example, HF solution), which will be described later with reference to FIGS. 6 and 7.

The apparatus 100 for removing photoresists according to some example embodiments includes an in-line mixer 150 configured to mix the ozone solution and the acid solution respectively supplied from the first and second supply lines 121 and 131. The ozone solution and the acid solution may be mixed by the in-line mixer 150, while flowing, before being supplied.

As illustrated in FIG. 1, the apparatus 100 may further include a transfer line 151, connected to the chamber 110 from a point where the first and second supply lines 121 and 131 are merged, and the in-line mixer 150 may be mounted in a region of the transfer line 151.

According to some example embodiments, since the ozone solution may be mixed with the acid solution using the in-line mixer 150 without use of a mixing means (for example, a mixing bath), activated ozone may be stably maintained at a dissolved state.

The acid solution is supplied from the acid solution reservoir 130 to the chamber 110 through the in-line mixer 150 using pressure applied from a conventional pump, whereas the ozone solution may be supplied to the chamber 110 through the in-line mixer 150 through a difference between an internal pressure of the ozone solution generator 120 and an internal pressure of the chamber 110. Loss of activated ozone, caused by a change in pressure, may be reduced by transferring the ozone solution in the above described manner, rather than applying pressure using a pump.

The in-line mixer 150 may employ a screw structure inside a tube. The ozone solution and the acid solution may be spontaneously mixed by a vortex generated by the screw structure while passing through the inside of the in-line mixer 150.

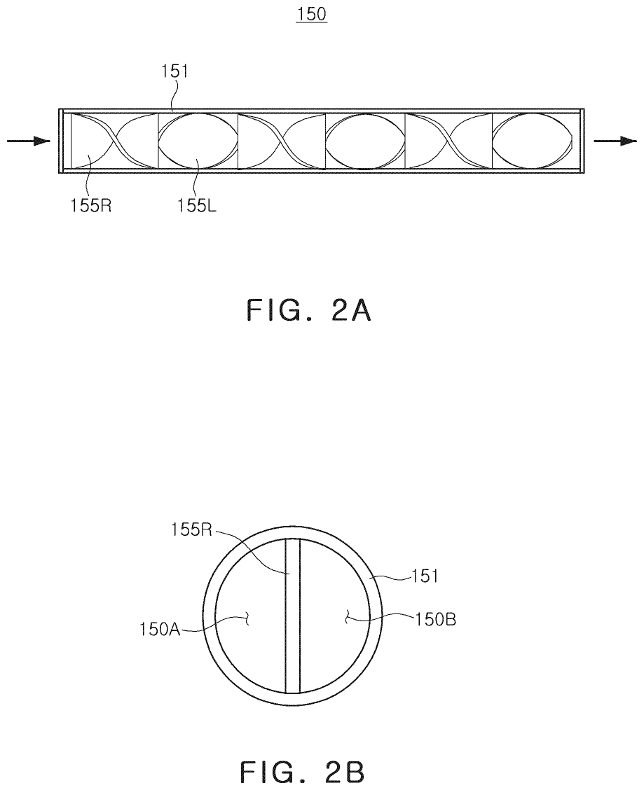

FIGS. 2A and 2B are a side cross-sectional view and an inlet cross-sectional view of an in-line mixer 150 employable in the apparatus 100 for removing photoresists in FIG. 1, respectively.

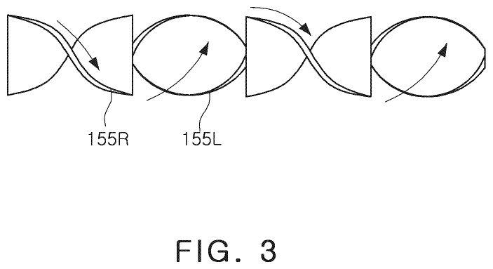

Referring to FIG. 2A, the in-line mixer 150 includes a tube 151 and screw structures 155R and 155L mounted inside the tube 151. A screw structure according to some example embodiments may include first and second screw pieces 155R and 155L, having opposite rotation directions in each section, alternately disposed in each section. As illustrated in FIG. 2B, an inlet of the in-line mixer 150 may divided into two regions 150A and 150B by the first screw piece 155R. An ozone solution and an acid solution may flow separately into the two regions 150A and 150B. The ozone solution and the acid solution may be effectively mixed while successively and alternately generating vortices, having opposite directions, by the first and second screw pieces 155R and 155L (see arrows in FIG. 3). In addition to the illustrated structure, the in-line mixer 150 may employ various structures well known in the field in which two or more fluids may be mixed while flowing.

As described above, the photoresist removing solution mixed by the in-line mixer 150, while flowing, may be supplied to the chamber 110 through the transfer line 151.

The chamber 110 may be substantially provided as a photoresist stripper. In some example embodiments, the chamber 110 may include a substrate support 115 and an injection nozzle unit 112 disposed on the substrate support 115. A substrate W, on which a photoresist pattern is formed, may be disposed on the substrate support 115. The injection nozzle unit 112 may be configured to inject the photoresist removing solution, supplied from the transfer line 151, to the substrate W disposed on the substrate support 115.

The injection nozzle unit 112 may be disposed over the substrate W to entirely overlap a top surface of the substrate W. The injection nozzle unit 112 may include a plurality of injection holes 114 regularly arranged to uniformly inject the photoresist removing solution. The inside of the injection nozzle unit 114 may be provided with a space in which the supplied photoresist removing solution is temporarily stored.

The apparatus 100 may include a temperature controller 116 configured to measure a temperature of the injection nozzle unit 112. A temperature of the photoresist removing solution may be maintained while the photoresist removing solution is supplied to the substrate W. In some example embodiments, the photoresist removing process may be performed at room temperature, for example, in a range of 10 to 25 degrees Celsius.

The substrate W may be, for example, a semiconductor substrate containing a semiconductor material such as single-crystalline silicon and/or single-crystalline germanium. A predetermined (or alternatively, given) pattern such as an insulating pattern and/or a conductive pattern may be formed on the substrate W. A photoresist pattern, provided as an etching mask, may be formed on the pattern. The substrate W may be loaded on a support 115 disposed at a lower portion of the chamber 110. According to some example embodiments, a plurality of substrates W may be loaded on the support 115. For example, a susceptor, having a plurality of slots, may be disposed on the support 115, and a substrate W may be loaded on each of the slots.

The support 115 may rotate while being coupled to a chuck 113. The chuck 113 may be disposed to penetrate the chamber 110. The photoresist removing solution may uniformly remove a photoresist in an entire region of the substrate W, while being injected, as the support 115 is rotated by the chuck 113. A lower portion of the chamber 110 may be provided with an outlet 119 to discharge a reactant to the outside of the chamber 110 after reacting with the substrate W, for example, a photoresist (residue).

In some example embodiments, the apparatus 100 may be combined with a photoresist ashing device or may be configured in such a manner that the chamber 110 performs an ashing function. The photoresist ashing device may include a unit configured to generate plasma or ultraviolet light. In this case, after a main portion of the photoresist pattern formed on the substrate W is preliminarily removed using the photoresist ashing device, the substrate W may be transferred to the chamber 110 of the apparatus 100 to remove the photoresist residue using a photoresist removing solution in which the ozone solution and the acid solution are mixed.

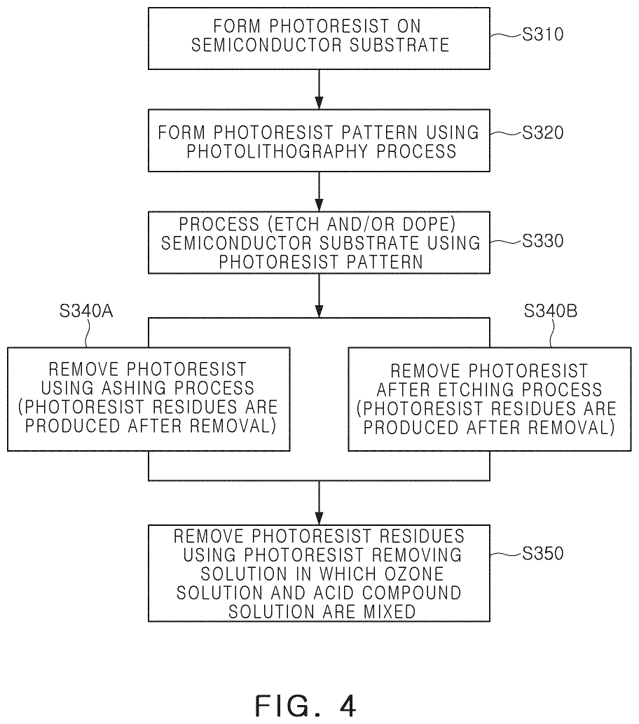

FIG. 4 is a flowchart illustrating a method of manufacturing a semiconductor device according to some example embodiments.

Referring to FIG. 4, a method for manufacturing a semiconductor device according to some example embodiments may include forming a photoresist pattern on a semiconductor substrate (S310).

A photoresist for patterning (etching) and/or impurity doping may be formed to manufacture a desired device on the semiconductor substrate. In some example embodiments, the photoresist is a resist for a KrF excimer laser (248 nm), a resist for an ArF excimer laser (193 nm), a resist for an F2 excimer laser (157 nm), and/or an extreme ultraviolet (EUV) (13.5 nm).

In operation S320, a photoresist pattern may be formed using a lithography process.

An exposure process may use radiation having various exposure wavelengths. For example, the exposure process may be performed at an exposure wavelength of i-line (365 nanometers (nm)), with a KrF excimer laser (248 nm), an ArF excimer laser (193 nm), an F2 excimer laser (157 nm) and/or Pr EVI (13.5 nm). After a selective exposure process is performed using a photomask, a post exposure baking (PEB) process and/or a development process may be performed to form a photoresist pattern.

In operation S330, the semiconductor substrate may be selectively processed using the photoresist pattern. The selective processing may include selectively etching an exposed region and/or selectively implanting impurities into the exposed region.

Removing the photoresist pattern may be performed. A photoresist residue may be produced even after removal of the photoresist pattern. An ashing process (S340A) may be further performed to remove the photoresist, but the photoresist pattern may be substantially removed in an etching process for patterning without an additional removing process (S340B). Since the photoresist residue produced after the ashing process or the etching process may cause a defect in a subsequent process, the photoresist residue may be removed through an additional cleaning process proposed by the present inventor.

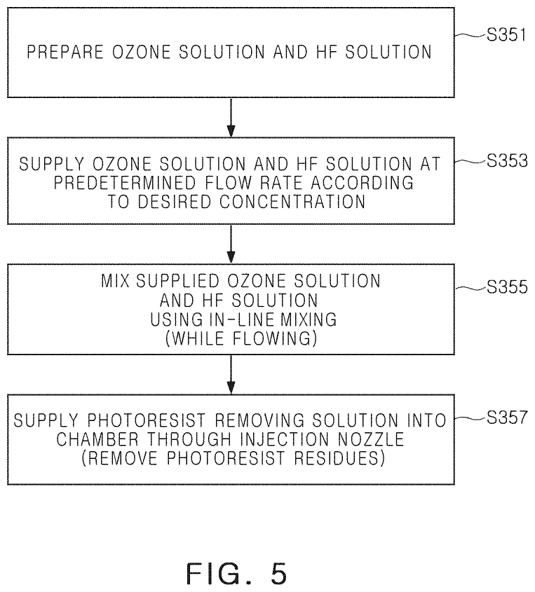

The photoresist residue may be removed using the photoresist removing solution obtained by mixing the ozone solution and the acid solution (S350). The process of removing the photoresist residue may be achieved by the process illustrated in FIG. 5.

First, an ozone solution and an acid solution (for example, HF solution) are prepared (S351). The ozone solution and the acid solution may be mixed at a suitable flow rate to obtain a desired concentration of photoresist removing solution (S353). Accordingly, the ozone concentration and the acid concentration of the photoresist removing solution may be adjusted by appropriately setting a ratio of the flow rates together with the respective concentrations of the ozone solution and the acid solution.

The ozone solution and the acid solution supplied at a predetermined (or alternatively, given) flow rate ratio may be mixed using in-line mixing to prepare a photoresist removing solution (S355). Accordingly, the ozone solution and the acid solution may be mixed, while flowing, without a separate mixing bath. In some example embodiments, the ozone concentration of the photoresist removing solution may be in the range of 10 to 200 ppm, and the acid concentration of the photoresist removing solution may be in the range of 100 to 1500 ppm.

The photoresist removing solution prepared by the in-line mixer (150 in FIG. 1) may be supplied into a chamber through an injection nozzle unit (S357) to effectively remove a photoresist residue on a substrate. A process of removing the photoresist residue may be performed at a room temperature, for example, in the range of 10 to 25 degrees Celsius.

Ozone should be provided at a sufficient concentration to enhance removability of the photoresist residue. However, when the concentration of ozone is high, other elements (such as a silicon nitride, and the like) may be oxidized by oxidation and such an oxide may be removed by the acid solution. Therefore, an upper limit of the ozone concentration may be appropriately set, and type and/or the acid concentration of the acid compound may be appropriately limited.

Table (1) illustrates etching rates depending on concentrations of ozone. Referring to Table (1), an etching target includes a photoresist cured with KrF (KrF-PR), an oxide formed by atomic layer deposition (ALD-Ox), and a silicon nitride formed by atomic layer deposition (ALD-SiN).

TABLE 1

| Concentration of | KrF-PR | ALD-Oₓ | ALD-SiN |
|---|---|---|---|
| O₃ (ppm) | (\acute{Å}) | (\acute{Å}) | (\acute{Å}) |
| 10 | 2.43 | 4.69 | 2.07 |
| 20 | 247.93 | 4.3 | 2.01 |
| 30 | 910.49 | 4.7 | 1.96 |
| 40 | 1482.72 | 7.68 | 2.13 |

The higher the concentration of ozone, the higher the removability of a photoresist. In the case in which the concentration of ozone is 20 ppm or more, the photoresist may be effectively removed to have an etching thickness of 247 angstroms (Å) or more, compared with an etching thickness of another material layer. When the concentration of ozone is 40 ppm, an etching thickness of an oxide film formed by atomic layer deposition (ALD-Ox) was increased slightly rather than significantly. Accordingly, the ozone concentration of the photoresist removing solution may be set in the range of 20 to 40 ppm in consideration of such conditions.

Etching rates of a silicon nitride and an oxide were measured by setting the concentration of ozone to 30 ppm, using a hydrofluoric acid (HF) solution as an acid solution, and changing the concentration of HF to 140 ppm, 170 ppm, 220 ppm, 260 ppm, 280 ppm, 300 ppm, 470 ppm, and 700 ppm. The measured etching rates are illustrated in the graphs of FIGS. 6 and 7. A comparative example illustrates an etching rate when only diluted sulfate peroxide (DSP) is used without an ozone solution.

Since an etching rate is significantly increased when the HF concentration is 470 ppm or more, a risk of etching and damaging another element such as an anti-reflective film or a mask may be increased. In contrast to the comparative example, in terms of an etching rate of an oxide (see FIG. 7), the HF concentration of the photoresist removing solution may have similar properties in the range of 200 to 350 ppm. Also, in terms of an etching rate of a silicon nitride (see FIG. 6), the etching rate was found to be higher than an etching rate in the comparative example when the etching rate is greater than 300 ppm.

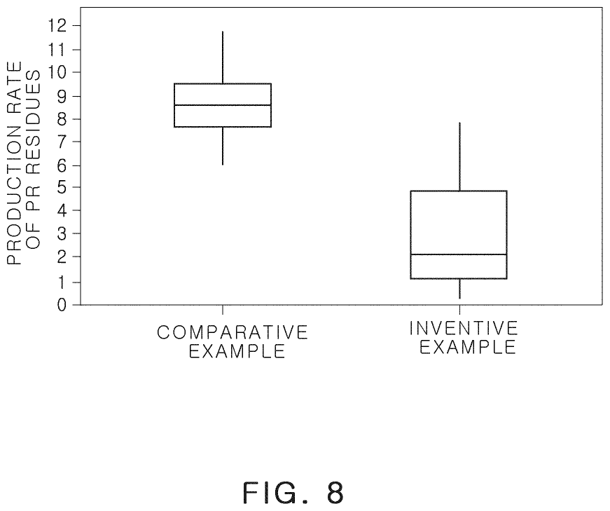

In the case in which the photoresist removing solution according to some example embodiments is applied to a photoresist stripping process, it was confirmed that a production rate of photoresist residue was reduced to 3.35% as compared with the DSP (8.7%), a stripper based on a sulfuric acid solution, and yield was improved to 0.15%, as illustrated in FIG. 8. Moreover, since a sulfuric acid solution is not used, an eco-friendly process may be implemented.

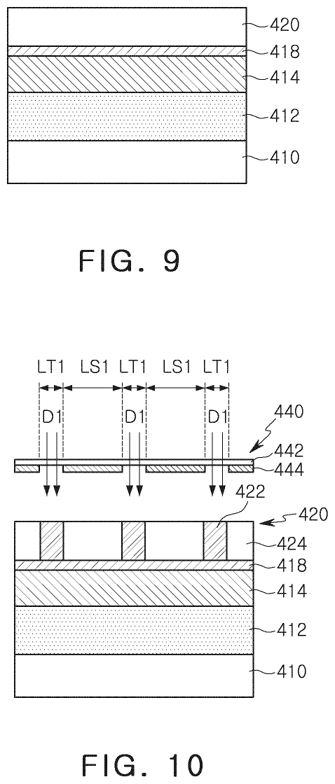

FIGS. 9 to 14 are cross-sectional views illustrating a method of manufacturing a semiconductor device according to some example embodiments.

Referring to FIG. 9, an etching target 412 and a hardmask layer 414 are sequentially formed on a substrate 410. An anti-reflective film 418 and a photoresist layer 420 are sequentially formed on the hardmask layer 414.

The substrate 410 may be a semiconductor substrate. In some example embodiments, the substrate 410 may be formed of a semiconductor such as silicon (Si) and/or germanium (Ge). In some example embodiments, the substrate 410 may include a compound semiconductor such as silicon-germanium (SiGe), silicon carbide (SiC), gallium arsenide (GaAs), indium arsenide (InAs), and/or indium phosphide (InP). In some example embodiments, the substrate 410 may have a silicon-on-insulator (SOI) structure. The substrate 110 may include a conductive region, for example, a well doped with impurities, or a structure doped with impurities. The substrate 410 may have various device isolation structures such as a shallow trench isolation (STI) structure.

The etching target 412 may be an insulating layer or a conductive layer. For example, the etching target 412 may be formed of a metal, an alloy, a metal carbide, a metal nitride, a metal oxynitride, a metal oxycarbide, a semiconductor, polysilicon, an oxide, a nitride, an oxynitride, and/or combinations thereof, but a material thereof is not limited thereto. When a pattern desired to be ultimately formed is directly implemented on the substrate 410, the etching target 412 may be omitted.

The hard mask layer 414 may be formed of various materials depending on type of the etching target 412. For example, the hardmask layer 414 may be an oxide layer, a nitride layer, a silicon carbon nitride (SiCN) layer, a polysilicon layer, an amorphous carbon layer (ACL), and/or a carbon-containing layer such as a spin on hardmask (SOH). A carbon-containing layer formed of the SOH material may include an organic compound having a relatively higher carbon content of about 85 to 99% by weight based on a total weight thereof. The organic compound may include a hydrocarbon compound, including an aromatic ring such as phenyl, benzene, and/or naphthalene, and/or a derivative thereof.

In some example embodiments, the anti-reflective film 418 may be formed to have a thickness of about 20 to 150 nm, but the thickness is not limited thereto. In some embodiments, the anti-reflective film 418 may be formed of an inorganic matter such as titanium, titanium dioxide, titanium nitride, chromium oxide, carbon, silicon nitride, silicon oxynitride, amorphous silicon, and/or the like. In some example embodiments, the anti-reflective film 418 may be omitted. In some example embodiments, an organic anti-reflective film may be disposed on the anti-reflective film 418, an inorganic film, in parallel or may replace the anti-reflective film 418.

The photoresist layer 420 may be formed of a positive tone photoresist or a negative tone photoresist. For example, in the case in which the photoresist layer 420 is formed of a positive tone photoresist, the photoresist layer 420 may include a resin having a polarity increased by an acid action. For example, the photoresist layer 420 may include a resin, including an acid-labile group, and/or a chemically amplified photoresist including a photo acid generator (PAG). The photoresist layer 420 may be formed using a resist for a KrF excimer laser (248 nm), a resist for an ArF excimer laser (193 nm), a resist for an F2 excimer laser (157 nm), and/or a resist for extreme ultraviolet (EUV) (13.5 nm). The photoresist layer 130 may be formed by a spin coating process.

Referring to FIG. 10, an exposure process is performed by aligning a photomask 440, having a plurality of light shielding areas LS1 and a plurality of light transmitting areas LT1, with a predetermined (or alternatively, given) location of the substrate 410 and exposing a first region 422 of the photoresist layer 420 through the plurality of transmitting areas LT1 of the photomask 440.

In the case in which the photoresist layer 420 is a positive tone photoresist, in a first region 422 of the photoresist layer 420, an acid-labile group is deprotected by acid generated by an exposure process and a polarity in the first region 422 may be larger than a polarity in the other portions of the photoresist layer 420. In the case in which the photoresist layer 420 is a negative tone photoresist, a polarity in the first region 422 of the photoresist layer 420 may be decreased to be smaller than a polarity in a second region 424 of the photoresist layer 420.

A size of the first region 422 may be adjusted by adjusting a dose D1. The photomask 440 includes a transparent substrate 442 and a plurality of light shielding patterns 444 formed in a plurality of light shielding regions LS1 on the transparent substrate 442. The transparent substrate 442 may be formed of quartz. The plurality of light shielding patterns 444 may be formed of chromium (Cr). The light transmitting region LT1 may be defined by the plurality of light shielding patterns 444.

In the case in which an immersion lithography process is used, a topcoat layer, not illustrated, may be further formed to cover the photoresist layer 420 before the exposure process in order to prevent a direct contact between the immersion liquid and the photoresist layer 420 and prevent components of the photoresist layer 420 from leaching into the immersion liquid. In some example embodiments, even when an immersion lithography process is used, the topcoat layer may be omitted by including a fluorine-containing additive in the photoresist layer 420.

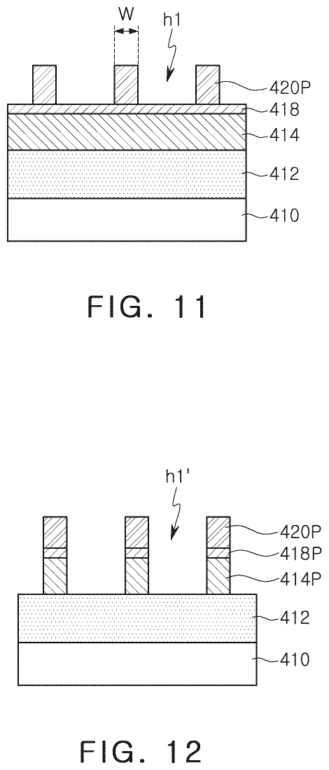

The dose D1 may be set according to a width WP of a photomask pattern 420P (see FIG. 11) to be formed from the photoresist layer 420 through the exposure process. The smaller the width W of the photomask pattern 420P to be formed, the larger a set value of the dose D1. The larger the width W of the photomask pattern 420P, the smaller the set value of the dose D1.

Referring to FIG. 11, when the photoresist layer 420 is a negative tone photoresist layer, an exposed photoresist layer 420 may be developed such that an unexposed region 424 of the photoresist layer 420 is selectively removed to form a photoresist pattern 420P including an exposed first region 422, as illustrated in FIG. 10. When the photoresist layer 420 is a positive tone photoresist, the exposed region 422 may be selectively removed such that the unexposed region 424 may be formed as a photoresist pattern.

After the photoresist pattern 420P is formed, the anti-reflective film 418 is exposed through an opening h1 penetrating the photoresist pattern 420P.

Referring to FIG. 12, the anti-reflective film 418 and a hard mask layer 414 are successively and anisotropically etched using the photoresist pattern 420P as an etching mask to form an anti-reflective film pattern 418P, in which an opening h1′ is formed, and the hard mask pattern 414P.

The anisotropic etching may be performed using a dry etching process, a wet etching process, or a combination thereof. The etching target 412 is exposed through the opening hr. In this case, at least a portion of the photoresist pattern 420P may be consumed to be thinned or removed.

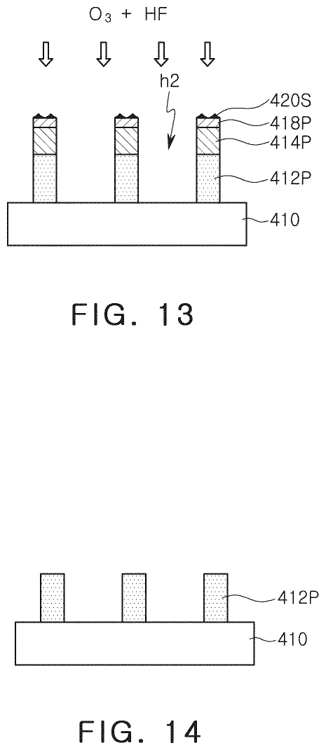

Referring to FIG. 13, the etching target 412 may be etched using the hard mask pattern 414P as an etching mask to form fine pattern 412P in which an opening h2 is formed.

The photoresist pattern 420P, thinned during formation of the fine pattern 412P, may also be etched to be removed. However, a photoresist residue 420S such as an organic matter or the like, partially remaining without being fully removed by the etching, may be produced. In some example embodiments, in the case in which an organic anti-reflective film is used, the organic matter may remain. As described above, various types of cured organic matter may remain.

The photoresist residue 420S, a cured organic matter, may be removed using a photoresist removing solution in which an ozone solution and an acid solution are mixed, as described above. The photoresist removing solution may be prepared by mixing an ozone solution and an acid solution using in-line mixing. Such a process of removing the photoresist residue 420S may be performed at room temperature. The ozone concentration of the photoresist removing solution may be in the range of 10 to 200 ppm and the acid concentration of the photoresist removing solution may be in the range of 100 to 1500 ppm.

Referring to FIG. 14, a top surface of the fine pattern 412P may be exposed by removing the hard mask pattern 414P remaining on the fine pattern 412P.

The photoresist residue 420S may be effectively removed to effectively prevent defective factors in a subsequent process. Moreover, since the ozone solution is decomposed in the solution and does not form a reaction product harmful to a human body, the amount of wastewater may be reduced to provide eco-friendly and economical advantages.

According to some example embodiments, organic matters such as photoresist residues may be effectively removed and an eco-friendly process may be implemented using a photoresist removing solution in which an ozone solution and an acid solution are supplied by in-line mixing.

While some example embodiments have been shown and described above, it will be apparent to those skilled in the art that modifications and variations could be made without departing from the scope of the present inventive concept as defined by the appended claims.

What is claimed is:

1. An apparatus for removing photoresists, comprising:
a chamber including a substrate support configured to support a substrate, and a nozzle unit disposed toward the substrate support;
an ozone solution generator configured to generate an ozone solution;
an acid solution reservoir configured to store an acid solution;
first and second supply lines connected to the ozone solution generator and the acid solution reservoir respectively; and
an in-line mixer configured to
prepare a photoresist removing solution by mixing the ozone solution supplied from the first supply line, and the acid solution supplied from the second supply line, and
supply the photoresist removing solution to the nozzle unit.

2. The apparatus of claim 1, further comprising,
first and second valves on the first and second supply lines, respectively, and
a flow rate controller configured to control the first and second valves, the first and second valves configured to control a flow rate of the ozone solution and a flow rate of the acid solution, respectively.

3. The apparatus of claim 2, further comprising:
a concentration meter configured to measure an ozone (O₃) concentration and an acid concentration of the photoresist removing solution supplied from the in-line mixer.

4. The apparatus of claim 3, wherein the flow rate controller is configured to control the flow rate of the ozone solution and the flow rate of the acid solution such that the ozone concentration is maintained in a range of 10 to 200 ppm.

5. The apparatus of claim 4, wherein the flow rate controller is configured to control the flow rate of the ozone solution and the flow rate of the acid solution such that the acid concentration is maintained in a range of 100 to 1500 ppm.

6. The apparatus of claim 1, further comprising,
first and second flowmeters on the first and second supply lines, respectively, and configured to monitor a flow rate of the ozone solution and a flow rate of the acid solution, respectively.

7. The apparatus of claim 1, wherein the in-line mixer includes a screw structure disposed in a flow space inside the in-line mixer.

8. The apparatus of claim 1, wherein the ozone solution is supplied into the chamber through the in-line mixer by a pressure difference between an internal pressure of the ozone solution generator and an internal pressure of the chamber.

9. The apparatus of claim 8, wherein the acid solution is supplied to the in-line mixer by a pump.

10. The apparatus of claim 1, wherein the acid solution includes at least one selected from the group consisting of hydrofluoric acid (HF), hydrochloric acid (HCl), phosphoric acid (H₃PO₄), tetramethylammonium hydroxide (TMAT), oxalic acid, and acetic acid.

11. The apparatus of claim 1, wherein the acid solution includes hydrofluoric acid (HF), and
the photoresist removing solution, supplied from the in-line mixer, has an ozone concentration of 20 to 40 ppm and an HF concentration of 200 to 350 ppm.

12. An apparatus for removing photoresists, comprising:
a chamber having an internal space;
an ozone solution generator configured to generate an ozone solution;
an acid solution reservoir configured to store an acid solution;
first and second supply lines, connected to the ozone solution generator and the acid solution reservoir respectively, including first and second valves configured to control flow rates of the ozone solution and the acid solution, respectively;
a transfer line having a first end connected to the first and second supply lines, and a second end connected to the internal space of the chamber;
an in-line mixer configured to,
prepare a photoresist removing solution by mixing the ozone solution supplied from the first supply line, and the acid solution supplied from the second supply line, and
supply the photoresist removing solution to the internal space of the chamber through the transfer line; and
a flow rate controller configured to control the first and second valves.

13. The apparatus of claim 12, further comprising,
a concentration meter configured to measure an ozone (O₃) concentration and an acid concentration of a photoresist removing solution supplied from the in-line mixer,
wherein the flow rate controller is configured to control the flow rate of the ozone solution and the flow rate of the acid solution such that the photoresist removing solution has a desired ozone concentration and a desired acid concentration.

14. The apparatus of claim 12, wherein the acid solution is an HF solution.

15. An apparatus for removing photoresists, comprising:
a chamber having an internal space;
an ozone solution generator configured to generate an ozone solution;
an acid solution reservoir configured to store an acid solution;
an in-line mixer configured to,
prepare a photoresist removing solution by mixing the ozone solution and the acid solution, and
supply the photoresist removing solution to the internal space of the chamber; and
a flow rate controller configured to control flow rates of the ozone solution and the acid solution.

16. The apparatus of claim 15, wherein the chamber includes a substrate support configured to support a substrate, and a nozzle unit configured to inject the photoresist removing solution supplied from the in-line mixer.

17. The apparatus of claim 16, wherein the nozzle unit entirely overlaps the substrate.

18. The apparatus of claim 16, wherein the nozzle unit includes a plurality of holes regularly arranged to inject the photoresist removing solution.

19. The apparatus of claim 15, wherein the flow rate controller is configured to control the flow rate of the ozone solution and the flow rate of the acid solution such that the ozone concentration is maintained in a range of 10 to 200 ppm and the acid concentration is maintained in a range of 100 to 1500 ppm.

20. The apparatus of claim 15, wherein the photoresist removing solution, supplied from the in-line mixer, has an ozone concentration of 20 to 40 ppm and an acid concentration of 200 to 350 ppm.
